(19) United States
(12) Patent Application Publication
(10) Pub. No.: US 2022/0069208 A1
(43) Pub. Date: Mar. 3, 2022

(54) RESISTIVE RANDOM ACCESS MEMORY AND METHOD FOR INITIALIZING THE SAME

(71) Applicant: NATIONAL SUN YAT-SEN UNIVERSITY, Kaohsiung City (TW)

(72) Inventors: Ting-Chang Chang, Kaohsiung City (TW); Yi-Ting Tseng, Kaohsiung City (TW); Chun-Chu Lin, Kaohsiung City (TW); Wen-Chung Chen, Kaohsiung City (TW); Shih-Kai Lin, Kaohsiung City (TW); Po-Hsun Chen, Kaohsiung City (TW)

(21) Appl. No.: 17/088,736

(22) Filed: Nov. 4, 2020

(30) Foreign Application Priority Data
Sep. 1, 2020 (TW) 109129877

(51) Int. Cl. H01L 45/00; H01L 27/24

(52) U.S. Cl. CPC H01L 45/1213; H01L 45/141; H01L 27/24; H01L 45/1246; H01L 45/1233

(57) ABSTRACT

A resistive random access memory and an initialization method thereof are disclosed. The initialization method includes irradiating a memory device with an electromagnetic wave and manipulating a switching voltage to switch the memory device between a high resistance state and a low resistance state. The electromagnetic wave has a frequency of above 10¹⁶ Hertz. The resistive random access memory includes a plurality of memory devices and a switching circuit respectively electrically connected to the plurality of memory devices. Each of the plurality of memory devices has a resistance-changing layer and two electrode layers respectively located on an upper surface and a lower surface of the resistance-changing layer.

### CROSS REFERENCE TO RELATED APPLICATION

The application claims the benefit of Taiwan application serial No. 109129877, filed on Sep. 1, 2020, and the entire contents of which are incorporated herein by reference.

### BACKGROUND OF THE INVENTION

### 1. Field of the Invention

The present invention relates to an electronic device and, more particularly, to a resistive random access memory irradiated by a high-energy electromagnetic wave and an initialization method thereof.

### 2. Description of the Related Art

Memory is a real-time data access device that must be used in various electronic products. With the trend of miniaturization of products, commonly used flash memory will be replaced by new technologies with high durability, low energy consumption, and faster read/write speed. Among them, resistive random access memory (RRAM) can operate at low current and perform resistive switching within nanoseconds, read/write repeatedly and store data for a long time. In addition, the resistive random access memory has the characteristics of small access data unit, which is suitable for miniaturized electronic products.

Please refer to FIG. 1, which shows conventional resistive random access memory 9. The conventional resistive random access memory 9 can be in an array structure formed by a plurality of memory units 91, with each of the plurality of memory units 91 having a variable resistance 92 and a transistor 93. An external selective circuit is used to apply different bias voltages to change the resistance value of each of the variable resistances 92. Thus, each of the plurality of memory units 91 can be switched between a high resistance state (HRS) and a low resistance state (LRS), which can be used to interpret the digital signals of 0 and 1 to achieve the function of accessing data.

Before starting to operate the resistance state switching, the above-mentioned conventional resistive random access memory 9 must go through an initialization process, that is, to apply an initialization voltage to each of the variable resistances 92, with the initialization voltage greater than the bias voltage required for the resistance state switching. Thus, each of the variable resistances 92 will undergo a soft breakdown and change from an insulating state to a variable resistance state. After the initialization is completed, each of the variable resistances 92 only needs a lower bias voltage to switch between the high and low resistance states. Therefore, this initialization step only needs to be performed once. However, with the miniaturization of the size of electronic devices, the portion of the electric field applied to the electronic devices dissipating from the sidewalls of the devices increases. Thus, the initialization voltage increases as the size of the resistive random access memory 9 reduces, which results in the conventional resistive random access memory 9 having to be provided with an amplifying circuit 94 to provide the voltage value required for the initialization step. Nevertheless, the amplifying circuit 94 is only used once, while requiring additional setting space. As a result, the number of memory units 91 that can be set in the same area of the conventional resistive random access memory 9 is reduced, which is unfavorable to the product miniaturization and increases the production cost and manufacturing process difficulty.

In light of this, it is necessary to improve the resistive random access memory and the initialization method thereof.

### SUMMARY OF THE INVENTION

In order to solve the above problems, it is an objective of the present invention to provide a method for initializing a resistive random access memory, which can simplify the manufacturing process of the memory.

It is another objective of the present invention to provide a method for initializing a resistive random access memory, which can avoid damage caused by high voltage.

It is a further objective of the invention to provide a resistive random access memory capable of reducing the product volume.

As used herein, the term “a” or “an” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

In an example, a method for initializing a resistive random access memory of the invention includes irradiating a memory device with an electromagnetic wave and manipulating a switching voltage to switch the memory device between a high resistance state and a low resistance state. The electromagnetic wave has a frequency of above 10¹⁶ Hertz.

In an example, a resistive random access memory of the invention includes a plurality of memory devices and a switching circuit respectively electrically connected to the plurality of memory devices. Each of the plurality of memory devices has a resistance-changing layer and two electrode layers respectively located on an upper surface and a lower surface of the resistance-changing layer.

Accordingly, in the resistive random access memory and its initialization method of the invention, the initializing process can be completed through irradiating the electromagnetic wave instead of increasing a voltage value, which can simplify the manufacturing process of the memory and can also eliminate the need for an additional amplifying circuit, so as to improve the area utilization rate of the memory substrate to achieve the effects of reducing product volume, saving production costs and reducing manufacturing process difficulty.

In an example, the electromagnetic wave has a frequency of above 10¹⁶ Hertz, and the electromagnetic wave E is an X-ray or a gamma ray. In this way, a high-energy electromagnetic wave can gather conductive materials in the device, which has the effect of accelerating the initialization process.

Among them, the resistance-changing layer includes an insulating material having carbon, nitrogen, oxygen, fluorine, silicon, sulfur, selenium or tellurium. In this way, the switching voltage can change the insulation characteristics of the resistance-changing layer, which has the effect of forming high and low resistance states.

In an example, each of the plurality of memory devices further has a current-limiting unit electrically connected to one of the two electrode layers. In this way, the current-limiting unit can control the upper limit of the current value passing through the resistance-changing layer, which has the function of avoiding overcurrent damage to the devices.

In an example, the plurality of memory devices forms an array structure through the switching circuit. In this way, through the switching circuit, it is possible to selectively apply voltage and change-over switch to each of the plurality of memory devices designated, which has the function of accessing information.

The present invention will become clearer in light of the following detailed description of illustrative embodiments of this invention described in connection with the drawings.

### BRIEF DESCRIPTION OF THE DRAWINGS

FIG. 1 is an installation diagram of a conventional resistive random access memory.

FIG. 2 shows an initialization process of a preferred embodiment of the invention.

FIG. 3 is an enlarged view of the memory device shown in FIG. 2.

FIG. 4 is a diagram comparing voltage values required for the invention and a conventional memory device to reach a soft breakdown state. For the invention, memory device is initialized without any voltage applied to reach a soft breakdown state.

FIG. 5 is a diagram showing the switching characteristic of high and low resistance states of a memory device of the preferred embodiment of the invention.

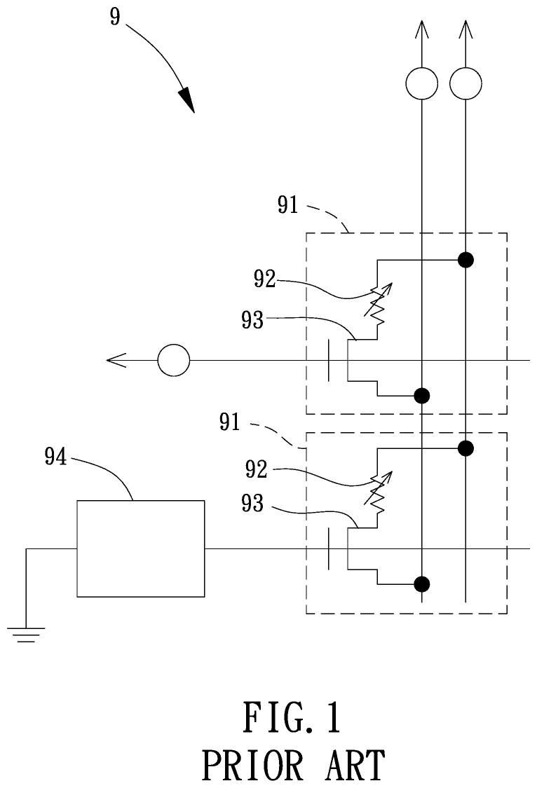

### DETAILED DESCRIPTION OF THE INVENTION

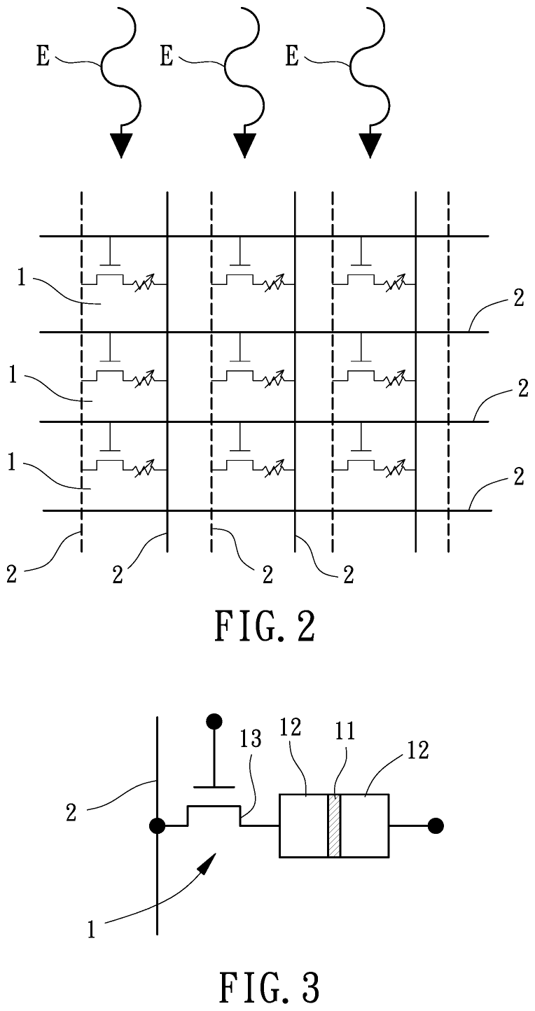

Please refer to FIG. 2, which shows an initialization process diagram of a preferred embodiment of the invention. The resistive random access memory includes a plurality of memory devices 1 and a switching circuit 2. The plurality of memory devices 1 is electrically connected with each other through the switching circuit 2.

Please refer to FIG. 3, each of the plurality of memory devices 1 has a resistance-changing layer 11 and two electrode layers 12 respectively located on an upper surface and a lower surface of the resistance-changing layer 11. The voltage between the two electrode layers 12 can switch high and low resistance states of the resistance-changing layer 11. The resistance-changing layer 11 may be insulating material including such as carbon (C), nitrogen (N), oxygen (O), fluorine (F), silicon (Si), sulfur (S), selenium (Se) or tellurium (Te) elements. Each of the plurality of memory devices 1 may also have a current-limiting unit 13, and the current-limiting unit 13 is electrically connected to one of the two electrode layers 12, such that the current-limiting unit 13 can control the upper limit of the current value passing through the resistance-changing layer 11 to avoid damaging each of the plurality of memory devices 1 by the current exceeding the load. In this embodiment, the current-limiting unit 13 is a transistor.

Please refer to FIG. 2, the switching circuit 2 can be respectively electrically connected to the two electrode layers 12 and the current-limiting unit 13 of each of the plurality of memory devices 1 through different circuits, such that the plurality of memory devices 1 forms an array structure. Therefore, the switching circuit 2 can selectively apply voltage to and switch between on and off of each of the designated plurality of memory devices 1.

In a preferred embodiment of the method for initializing a resistive random access memory of the invention is to irradiate an electromagnetic wave E to the plurality of memory devices 1, such that the resistance-changing layer 11 becomes a variable resistance state to complete the initialization of the resistive random access memory. The frequency of the electromagnetic wave E is above 10¹⁶ Hertz, and the electromagnetic wave E can be an X-ray or a gamma ray; a switching voltage is applied to the plurality of memory devices 1 through the switching circuit 2 to switch each of the plurality of memory devices 1 to high or low resistance states.

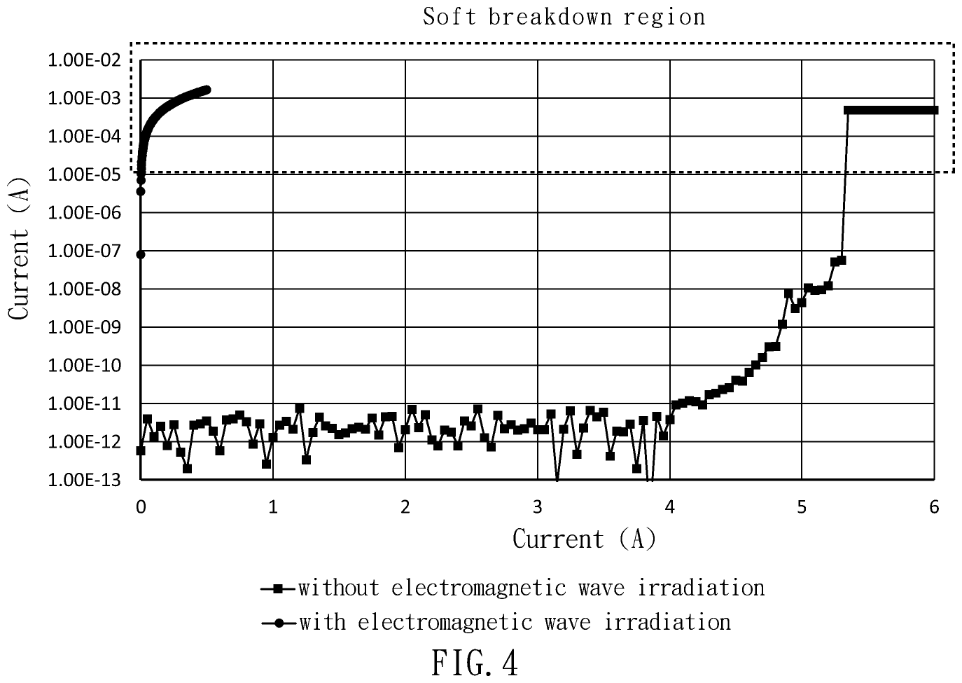

Please refer to FIGS. 3 and 4, the electromagnetic wave E is irradiated to the resistance-changing layer 11 of the plurality of memory devices 1, such that the conductive materials in the resistance-changing layer 11 gather to form a dendritic path, and conduct the two electrode layers 12 to cause a soft breakdown state. At this time, the plurality of memory devices 1 can be transformed into a variable resistance state (the step is called “forming”). After that, the switching voltage can be selectively applied to break or connect a conducting path. When the conducting path is broken, the plurality of memory devices 1 returns from a low resistance state to a high resistance state (the step is called “reset”). When the conducting path is connected, the plurality of memory devices 1 returns from the high resistance state to the low resistance state (the step is called “set”). FIG. 4 shows a comparison diagram in which the plurality of memory devices 1 can achieve a soft breakdown state with and without the electromagnetic wave E irradiation. When the plurality of memory devices 1 is not irradiated with the electromagnetic wave E, a voltage value of more than 5 volts must be applied to the resistance-changing layer 11 to cause a current passing through the resistance-changing layer 11 to rise sharply to reach a soft breakdown state. When the plurality of memory devices 1 is irradiated with the electromagnetic wave E, the resistance-changing layer 11 completes the initialization process directly, and only requires a voltage of less than 0.1 volts to be applied to the resistance-changing layer 11 to allow a large amount of current to pass through the resistance-changing layer 11. Therefore, irradiating with the electromagnetic wave E can replace applying of a higher voltage value, which has the effect of simplifying the difficulty of the manufacturing process.

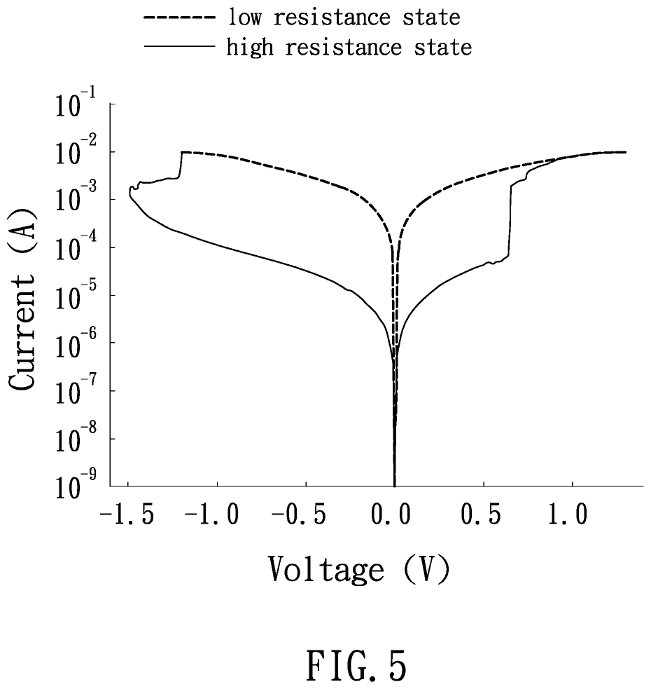

Please refer to FIGS. 2 and 5, when the plurality of memory devices 1 is switching to high or low resistance states, a range of the switching voltage controlled by the switching circuit 2 is plus or minus 1.5 volts. By using the initialization method of the invention to perform the memory initialization process, the plurality of memory devices 1 only needs to be irradiated with the electromagnetic wave E, without the need for an additional amplifying circuit to provide a voltage larger than that controlled by the switching circuit 2, thus has the effect of reducing production costs.

In summary, the resistive random access memory and the initialization method of the invention complete the initialization process by irradiating the electromagnetic wave instead of applying a voltage value, which can simplify the manufacturing process of the memory and also eliminate the need for an additional amplifying circuit, so as to improve the area utilization rate of the memory substrate, achieving the effects of reducing product volume, saving production costs and reducing manufacturing process difficulty.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A method for initializing a resistive random access memory, comprising:
irradiating a memory device with an electromagnetic wave, wherein the electromagnetic wave has a frequency of above 10¹⁶ Hertz; and
manipulating a switching voltage to switch the memory device between a high resistance state and a low resistance state.

2. The method for initializing a resistive random access memory as claimed in claim 1, wherein the electromagnetic wave is an X-ray or a gamma ray.

3. A resistive random access memory manufactured according to the method for initializing a resistive random access memory as claimed in claim 1, comprising:
a plurality of memory devices, wherein each of the plurality of memory devices has a resistance-changing layer and two electrode layers respectively located on an upper surface and a lower surface of the resistance-changing layer; and
a switching circuit respectively electrically connected to the plurality of memory devices.

4. The resistive random access memory as claimed in claim 3, wherein the resistance-changing layer includes an insulating material having carbon, nitrogen, oxygen, fluorine, silicon, sulfur, selenium or tellurium.

5. The resistive random access memory as claimed in claim 3, wherein each of the plurality of memory devices further comprises a current-limiting unit electrically connected to one of the two electrode layers.

6. The resistive random access memory as claimed in claim 3, wherein the plurality of memory devices forms an array structure through the switching circuit.
